(19) United States
(12) Patent Application Publication
(10) Pub. No.: US 2009/0251950 A1
(43) Pub. Date: Oct. 8, 2009

(54) Integrated Circuit, Memory Cell Arrangement, Thermal Select Magneto-Resistive Memory Cell, Method of Operating a Thermal Select Magneto-Resistive Memory Cell, and Method of Manufacturing a Thermal Select Magneto-Resistive Memory Cell

(76) Inventor: Ulrich Klostermann, Munich (DE)

Correspondence Address: SLATER & MATSIL, L.L.P., 17950 PRESTON ROAD, SUITE 1000, DALLAS, TX, 75252, US

(21) Appl. No.: 12/099,699

(22) Filed: Apr. 8, 2008

(51) Int. Cl. G11C 11/00

(52) U.S. Cl. 365/158

(57) ABSTRACT

According to one embodiment of the present invention, an integrated circuit includes a thermal select magneto-resistive memory cell. The memory cell includes a stack of layers including a storage memory layer. The memory cell also includes a heating element which covers at least a part of the sidewalls of the stack of layers and which is electrically coupled to the stack of layers such that a heating current routed between the top end and the bottom end of the stack of layers is at least partly routed through the heating element.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic perspective view of a part of an integrated circuit including magneto-resistive memory cells;

FIG. 2 shows a circuit usable in conjunction with the integrated circuit of FIG. 1;

FIG. 3 shows a schematic cross-sectional view of a memory cell of an integrated circuit according to one embodiment of the present invention;

FIG. 4 shows a schematic cross-sectional view of a memory cell of an integrated circuit according to one embodiment of the present invention;

FIG. 5 shows a schematic cross-sectional view of a memory cell of an integrated circuit;

FIG. 6 shows a schematic cross-sectional view of a memory cell of an integrated circuit according to one embodiment of the present invention;

FIG. 7 shows the resistance and the heat power over the temperature within a part of an integrated circuit according to one embodiment of the present invention;

FIG. 8 shows the magnetic resistance and the current ratio over the temperature within a part of an integrated circuit according to one embodiment of the present invention;

FIG. 9 shows the heat power and the resistance of the temperature within a part of an integrated circuit according to one embodiment of the present invention;

FIG. 10 shows a schematic cross-sectional view of a memory cell of an integrated circuit according to one embodiment of the present invention;

FIG. 11 shows a flow chart of a method of operating an integrated circuit according to one embodiment of the present invention;

FIG. 12A shows a schematic perspective view of a memory module according to one embodiment of the present invention;

FIG. 12B shows a schematic perspective view of a memory module according to one embodiment of the present invention;

FIG. 13 shows a schematic cross-sectional view of a phase changing memory cell; and

FIG. 14 shows a schematic view of an integrated circuit using phase changing memory cells.

### DETAILED DESCRIPTION OF ILLUSTRATIVE EMBODIMENTS

According to one embodiment of the present invention, an integrated circuit including a resistivity changing memory cell is provided, wherein the memory cell includes a stack of layers including a storage memory layer, and wherein the memory cell includes a heating element which covers at least a part of the side walls of the stack of layers and is electrically coupled to the stack of layers such that a heating current routed between the top end and the bottom end of the stack of layers is at least partly routed through the heating element.

Within the scope of the present invention, the term “stack of layers” may be a stack of layers having a vertical stacking direction or a lateral stacking direction (90° stacking direction shift).

According to one embodiment of the present invention, the memory cell is a thermal select magneto-resistive memory cell or a phase changing memory cell. Also other types of resistivity changing memory cells are possible.

According to one embodiment of the present invention, the heating element covers the side walls of a tunneling junction barrier layer.

According to one embodiment of the present invention, the electrical resistance of the heating element decreases when increasing the temperature of the heating element.

According to one embodiment of the present invention, the electrical resistance of the heating element is high at room temperature, and low at temperatures occurring during memory cell writing processes.

According to one embodiment of the present invention, the heating element includes or consists of semiconducting material.

According to one embodiment of the present invention, the heating element includes or consists of germanium.

According to one embodiment of the present invention, the height of the heating element is about 5 nm to about 10 nm.

According to one embodiment of the present invention, the stack of layers includes a reference memory layer being disposed above or below the storage memory layer.

According to one embodiment of the present invention, the stack includes a barrier layer disposed between the reference memory layer and the storage memory layer.

According to one embodiment of the present invention, the electrical resistances of at least some layers of the stack are chosen such that the majority of a heating current flowing through the memory cell is forced to flow through the heating element.

According to one embodiment of the present invention, the stack includes a first tunneling junction barrier layer and a second tunneling junction barrier layer disposed above the first tunneling junction barrier layer, wherein the vertical position of the top surface of the second tunneling junction barrier layer is lower than the vertical position of the top end of the heating element, wherein the vertical position of the bottom surface of the first tunneling junction barrier layer is higher than the vertical position of the bottom end of the heating element.

According to one embodiment of the present invention, the heating element is a sidewall spacer.

According to one embodiment of the present invention, a memory cell arrangement including a plurality of resistivity changing memory cells is provided, wherein each memory cell includes a stack of layers, wherein each stack of layers includes a storage memory layer, wherein each memory cell includes a heating element which covers at least a part of the side walls of the stack of layers and is arranged such that a heating current routed between the top end and the bottom end of the stack of layers is split into a first current routed through all layers of the stack of layers, and a second current routed through the heating element.

According to one embodiment of the present invention, a resistivity changing memory cell is provided, wherein the memory cell includes a stack of layers including a storage memory layer, wherein the memory cell includes a heating element being disposed adjacent to or close to the storage memory layer, wherein the heating element covers at least a part of the side walls of the stack of layers and is electrically coupled to the stack of layers such that a heating current routed between the top end and the bottom end of the stack of layers is at least partly routed through the heating element.

According to one embodiment of the present invention, a method of operating a resistivity changing memory cell of an integrated circuit is provided, wherein the memory cell includes a stack of layers including a storage memory layer, and a heating element which covers at least a part of the side walls of the stack of layers, the method including: routing a heating current between the top end and the bottom end of the stack of layers such that at least a part of the heating current is routed through the heating element.

According to one embodiment of the present invention, the heating element covers the side walls of a tunneling junction barrier layer.

According to one embodiment of the present invention, the electrical resistance of the heating element decreases when increasing the temperature of the heating layer.

According to one embodiment of the present invention, the electrical resistance of the heating element is high at room temperature, and low at temperatures occurring during memory cell writing processes.

According to one embodiment of the present invention, the heating element includes or consists of semiconducting material.

According to one embodiment of the present invention, the heating element includes or consists of germanium.

According to one embodiment of the present invention, the height of the heating element is about 5 nm to about 10 nm.

According to one embodiment of the present invention, the stack of layers includes a reference memory layer being disposed above or below the storage memory layer.

According to one embodiment of the present invention, the stack includes a barrier layer disposed between the reference memory layer and the storage memory layer.

According to one embodiment of the present invention, the electrical resistances of at least some layers of the stack are chosen such that the majority of a heating current flowing through the memory cell is forced to flow through the heating element.

According to one embodiment of the present invention, the stack includes a first tunneling junction barrier layer and a second tunneling junction barrier layer disposed above the first tunneling junction barrier layer, wherein the vertical position of the top surface of the second tunneling junction barrier layer is lower than the vertical position of the top end of the heating element, wherein the vertical position of the bottom surface of the first tunneling junction barrier layer is higher than the vertical position of the bottom end of the heating element.

Since the embodiments of the present invention can be applied to magneto-resistive memory devices which include resistivity changing memory cells (magneto-resistive memory cells), a brief discussion of magneto-resistive memory devices will be given. Magneto-resistive memory cells involve spin electronics, which combines semiconductor technology and magnetics. The spin of an electron, rather than the charge, is used to indicate the presence of a “1” or “0”. One such spin electronic device is a magnetic random-access memory (MRAM), which includes conductive lines positioned perpendicular to one another in different metal layers, the conductive lines sandwiching a magnetic stack. The place where the conductive lines intersect is called a cross-point. A current flowing through one of the conductive lines generates a magnetic field around the conductive line and orients the magnetic polarity into a certain direction along the wire or conductive line. A current flowing through the other conductive line induces the magnetic field and can also partially turn the magnetic polarity. Digital information, represented as a “0” or “1” is stored in the alignment of magnetic moments. The resistance of the magnetic component depends on the moment's alignment. The stored state is read from the element by detecting the component's resistive state. A memory cell may be constructed by placing the conductive lines and cross-points in a matrix structure or array having rows and columns.

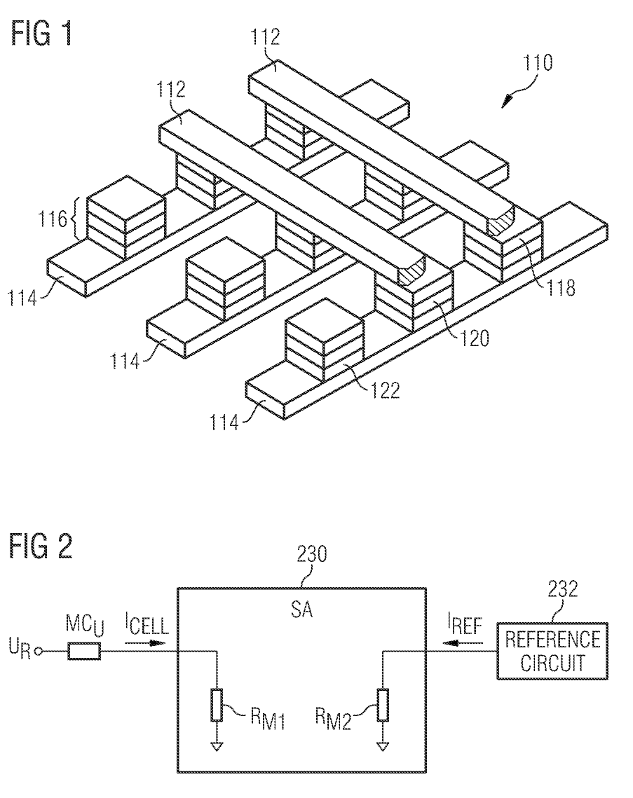

FIG. 1 illustrates a perspective view of a MRAM device 110 having bit lines 112 located orthogonal to word lines 114 in adjacent metallization layers. Magnetic stacks 116 are positioned between the bit lines 112 and word lines 114 adjacent and electrically coupled to bit lines 112 and word lines 114. Magnetic stacks 116 preferably include multiple layers, including a soft layer 118, a tunnel layer 120, and a hard layer 122, for example. Soft layer 118 and hard layer 122 preferably include a plurality of magnetic metal layers, for example, eight to twelve layers of materials such as PtMn, CoFe, Ru, and NiFe, as examples. A logic state is storable in the soft layer 118 of the magnetic stacks 116 located at the junction of the bitlines 112 and word lines 114 by running a current in the appropriate direction within the bit lines 112 and word lines 114 which changes the resistance of the magnetic stacks 116.

In order to read the logic state stored in the soft layer 118 of the magnetic stack 116, a schematic such as the one shown in FIG. 2, including a sense amplifier (SA) 230, is used to determine the logic state stored in an unknown memory cell MCᵤ. A reference voltage U_{R} is applied to one end of the unknown memory cell MCᵤ. The other end of the unknown memory cell MCᵤ is coupled to a measurement resistor Rₘ₁ The other end of the measurement resistor Rₘ₁ is coupled to ground. The current running through the unknown memory cell MCᵤ is equal to current I_{cell}. A reference circuit 232 supplies a reference current I_{ref} that is run into measurement resistor Rₘ₂. The other end of the measurement resistor Rₘ₂ is coupled to ground, as shown.

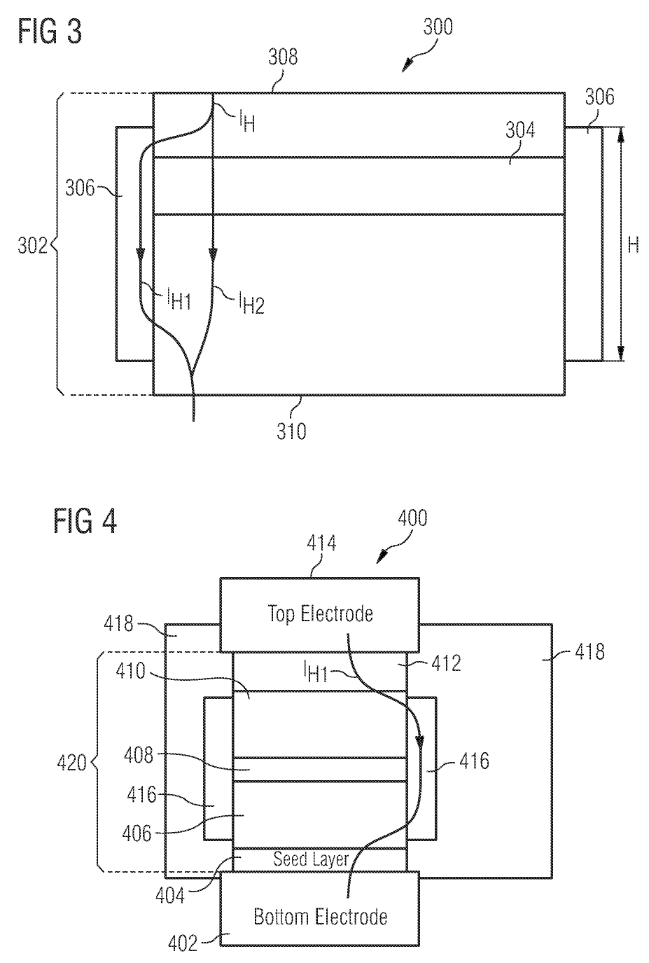

FIG. 3 shows a part of an integrated circuit which includes at least one thermal select magneto-resistive memory cell 300. The memory cell 300 includes a stack of layers 302. The stack of layers 302 includes a spacer layer 304. The spacer layer 304 may, for example, be a tunnel barrier made of Al₂O₃ or MgO. The spacer layer 304 may also serve to additionally generate heat (resistive heating) at elevated currents flowing through the memory cell 300. The memory cell 300 further includes a heating element 306 which covers at least a part of the side walls of the stack of layers 302 and which is electrically coupled to the stack of layers 302 such that a heating currents I_{H} which is used to heat the stack of layers 302 up to a particular temperature and which is routed between the top end 308 and the bottom end 310 of the stack of layers 302 is at least partially routed through the heating element 306.

In FIG. 3, the heating current I_{H} splits into a first heating current I_{H1} flowing through the heating element 306, and a second heating current I_{H2} flowing through the stack of layers 302, in particular through the spacer layer 304. Since the heating current I_{H} splits into the first heating current I_{H1} and the second heating current I_{H2}, it is possible to heat the stack of layers 302 without routing high currents through the stack of layers 302, in particular through the spacer layer 304. Thus, the requirements of the stack of layers 302 (or parts of the stack of layers 302) concerning current strength robustness can be reduced. The reduced requirements concerning current strength robustness may be exploited for increasing memory state reading characteristics of the memory cell 300.

According to one embodiment of the present invention, the heating element 306 covers the side walls of the spacer layer 304.

According to one embodiment of the present invention, the electrical resistance of the heating element 306 decreases when the temperature of the heating element 306 increases. One effect of this embodiment is that the majority of the heating current I_{H} is routed through the heating element 306 as soon as the temperature of the heating element 306 (i.e., the temperature of the memory cell 300) has reached a critical temperature. For example, the materials of the heating element 306 may be chosen such that the electrical resistance of the heating element 306 is high at room temperature, but low at temperatures occurring during memory cell writing processes (during which the stack of layers 302 is heated). The initial heating up to intermediate cross over temperature will be primarily generated by the stack of layers 302, in particular by the spacer layer 304. Then (at temperatures above intermediate cross over temperatures), the heat generation will be mainly supported and boosted by the side wall heating element 306.

According to one embodiment of the present invention, the heating element 306 includes or consists of semiconducting material. For example, the heating element 306 includes or consists of germanium or silicon.

According to one embodiment of the present invention, the stack of layers 302 includes a magnetic reference memory layer and a magnetic storage memory layer (not shown in FIG. 3) respectively arranged adjacent to the spacer layer 304. In order to read out the memory state of the magneto-resistive memory cell, the relative orientation of the magnetizations of the storage memory layer and the reference memory layer is detected by routing a memory state detecting current through the stack of layers 302, i.e., through the spacer layer 304 and the reference memory layer and storage memory layer arranged adjacent thereto.

According to one embodiment of the present invention, the heating element 306 is a sidewall spacer of the stack of layers 302. In this case, the height H of the heating element 306 (spacer) may, for example, be about 10 nm. However, the invention is not restricted thereto.

FIG. 4 shows a schematic cross-sectional view of a part of an integrated circuit having a magneto-resistive memory cell 400. The integrated circuit 400 includes a bottom electrode 402, a seed layer 404 arranged on the bottom electrode 402, a reference system 406 including at least a reference memory layer, a barrier layer 408, a storage system 410 comprising at least a storage memory layer, a via layer 412 arranged on the storage system 410, and a top electrode 414 arranged on the via layer 412. The integrated circuit 400 further includes a heating element 416 which covers a part of the sidewalls of the stack of layers 420 disposed between the bottom electrode 402 and the top electrode 414, namely a part of the sidewalls of the layers of the reference system 406, a part of the sidewalls of the layers of the storage system 410, and the sidewalls of the barrier layer 408.

The electrical resistances of at least some layers disposed between the bottom electrode 402 and the top electrode 414 may be chosen such that the majority of a heating current flowing between the bottom electrode 402 and the top electrode 414 is forced to flow through the heating element 416 above a critical cross over temperature. For example, the resistance of the storage system 410 and of the reference system 406 maybe chosen relatively high, thereby forcing the heating current to bypass the barrier layer 408 using the heating element 416. In this way, it is possible to optimize the properties of the storage system 410, the reference system 406, and the barrier layer 408 for memory state reading processes.

The whole stack of layers 420 shown in FIG. 4 is surrounded by insulating material 418, for example the dielectric material.

It is to be understood that each of the layers 404, 406, 408, 410, 412 and 416 may respectively consists of a plurality of sublayers.

When routing a heating current I_{H} between the top electrode 414 and the bottom electrode 402, a first part I_{H1} of the heating current I_{H} flows through the heating element 416, and a second part I_{H2} of the heating current flows through the stack of layers 420. As a consequence, the temperature of the heating element 416 is increased, thereby also heating the layers of the storage system 410. As soon as the temperature of the layers of the storage system 410 have reached a corresponding temperature threshold value (“blocking temperature”), the memory state of the storage memory layer included in the storage system 410 can be programmed using a magnetic field generated by a programming current, which is passed by in a current wire. Then, the heating current is terminated, thereby allowing the stack of layers 420 to cool down.

As has become apparent, the characteristics of the layers of the stack 420 (for example, the magnetic resistance of the stack 420) can be optimized for memory state readout processes since the stack of layers 420 does not have to “withstand” high heating currents. It is noted that the current by-pass through the heating element may reduce the available read out signal for the different resistance states (current shunting).

In contrast, FIG. 5 shows a schematic cross-sectional view of a part of an integrated circuit including a magneto-resistive memory cell 500 in which the stack of layers 520 has to cope with high heating currents and has to have good readout characteristics. As a consequence, the stack of layers 520 can not be fully optimized for memory state readout processes. It should be mentioned that the architecture of the reference system 406 and of the storage system 410 shown in FIG. 5 may be applied to the reference systems and the storage systems of all embodiments of the present invention.

In this embodiment, the reference system 406 arranged on the seed layer 404 (which may, for example, include or consist of Ta or Ru or Cu) includes the following layers: A PtMn layer 512 and an artificial antiferromagnetic structure including a ferromagnetic pinned layer 510 (which may, for example, include or consist of Co, CoFe or CoFeB), an antiferromagnetic coupling layer 508 (which may, for example, include or consist of Ru or Cu or Cr), and a reference layer 506 (which may, for example, include or consist of CoFe or CoFeB).

In this embodiment, the storage system 410 includes the following layers: On the barrier layer (e.g., including or consisting of Al₂O₃ or MgO or Cu), a soft magnetic storage layer 504 (e.g., including or consisting of Co or Fe or NiFe or CoFeB or CoFeZr or CoFe or CoFeTb) is arranged which is pinned to a natural antiferromagnetic layer 502 (e.g., including or consisting of IrMn) and which has a lower blocking temperature than the natural antiferromagnetic layer 502 of the reference system. At an elevated temperature above a critical blocking temperature of the storage system 410, the direction of the soft magnetic storage layer 504 can be freely changed by an applied magnetic field, while at a temperature below this critical blocking temperature the soft magnetic storage layer 504 is pinned to the natural antiferromagnetic layer 502 and is not be significantly changed even after having applied a very large (strong) disturb magnetic field.

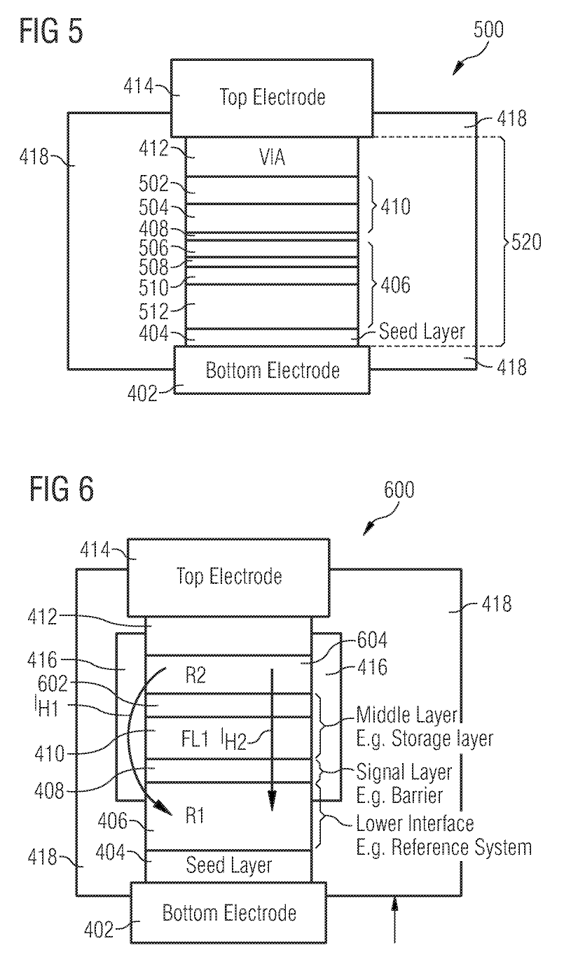

FIG. 6 shows schematic cross-sectional view of a part of an integrated circuit according to one embodiment of the present invention. The integrated circuit includes a memory cell 600 having the same architecture as the memory cell 400 except that a further barrier layer 602 and a further reference system 604 (which has the same purpose as the reference system 404 and may also include a plurality of sublayers) arranged on the further barrier layer 602 are disposed between the via layer 412 and the storage system 410.

Due to the use of further layers (further barrier layer 602 and further reference system 604), the length of the current path within the heating element 416 is increased, i.e., is longer than that within the heating element 416 of the memory cell 400. Thus, the heating effect of the heating element 416 can be increased.

By choosing high resistive materials for the layers 602, 604, 404, 408, and 410, the strength of the heating current I_{H1} can be set. This also applies to layer architectures being different from the layer architectures shown in FIGS. 4 to 6.

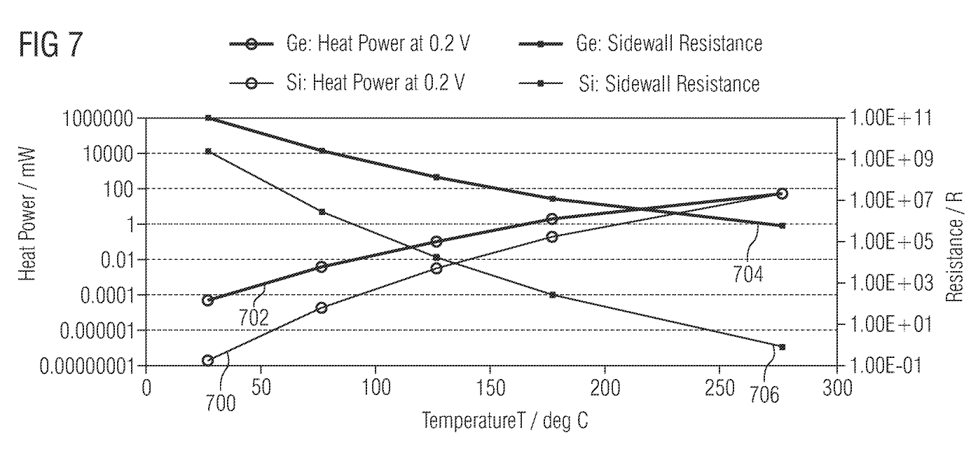

FIG. 7 shows the electrical resistance 704 of silicon heating material, and the electrical resistance 706 of germanium heating material over the temperature. As can be derived from FIG. 7, the electrical resistances of those materials decrease with increasing temperature.

FIG. 7 also shows that, as the resistance changes with the temperature, the heating power 700 for silicon (or 702 for germanium) of the side wall spacer also changes when assuming a constant heating voltage of 200 mV. Consequently, the increase in heating power with temperature will result in an increased temperature of the material, resulting in a self-boosting process.

One effect of heating materials having characteristics as shown in FIG. 7 is that the higher the temperature of the heating material becomes, the higher the heating current flowing through the heating element will be, i.e., the lower a current strength flowing through the stack of layers (memory storage layer/memory reference layer) will be during the heating process.

The effect shown in FIG. 7 may additionally be influenced using n- or p-doping of the heating material.

Similar characteristics as the semiconducting material as shown in FIG. 7 may also have carbon or diamond like spacers which are N₂ doped. This material may also be used as heating material.

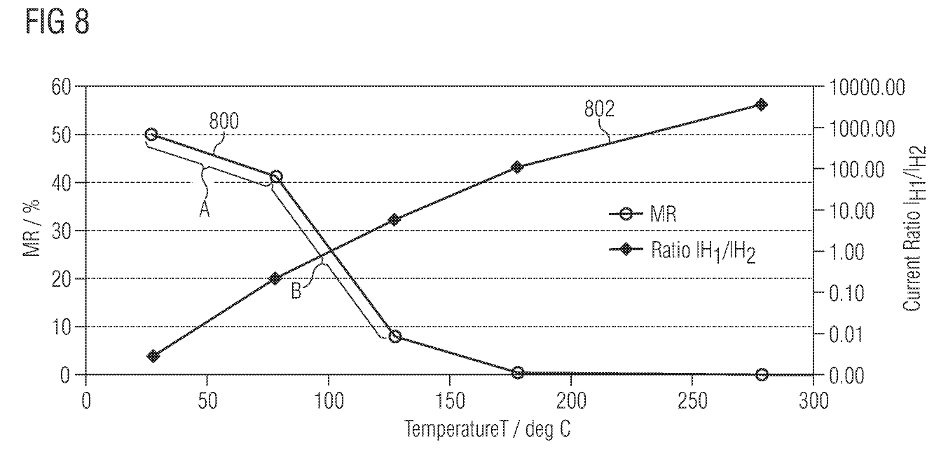

FIG. 8 shows the magnetic resistance ratio 800 of a tunnel barrier, e.g., the barrier layer 408, over the temperature. The magneto resistance ratio is given by MR:=(R1−R0)/R0, where R0 is the low resistance state, and R1 is the high resistance state of the memory cell. As the state sensitive current I_{H2} is shunted by I_{H1}, the original MR ratio of the MTJ stack is reduced depending on the resistance of the side wall heating element 416. As the side wall heating element is a function of the temperature, the effective MR is also a function of the temperature. As can be derived from FIG. 8, the magnetic resistance 800 decreases with increasing temperature. The magnetic resistance is high within a region A representing a temperature range used during reading processes. The magnetic resistance 800 further shows an area B representing temperatures used during writing processes. Within area B, the magnetic resistance ratio shows a significant drop which, however, is not problematic, since, during the writing process, no high magnetic resistance ratio is needed.

According to one embodiment of the present invention, a small magneto resistance ratio is used at heating conditions as this favors a symmetric heating behavior for the parallel and antiparallel state.

FIG. 8 further shows a current ratio I_{H1}/I_{H2}, i.e., the ratio of the current flowing, for example, through the heating element 416 (I_{H1}) and a current flowing through the stack of layers 420 (I_{H2}). This current ratio is indicated by graph 802 which increases with increasing temperature.

The temperature shown in FIG. 8 is the temperature of the side wall heating element 416 assuming that the resistance of the barrier layer 408 is 2700 Ohm and has a MR ratio of 50% at room temperature. As can be derived from FIG. 8, good magnetic resistance signals of 40% are obtained at read conditions at 75° C., whereas huge heating currents (100 times larger than during the reading processes) can be driven through the heating element 416 at elevated temperatures.

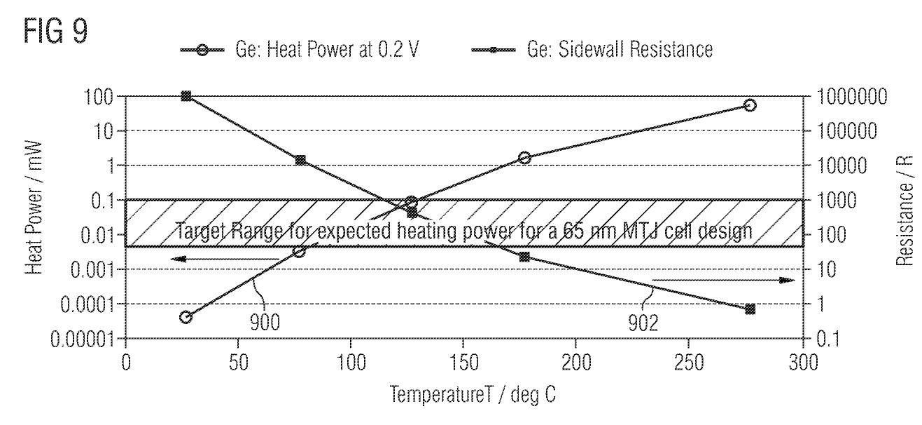

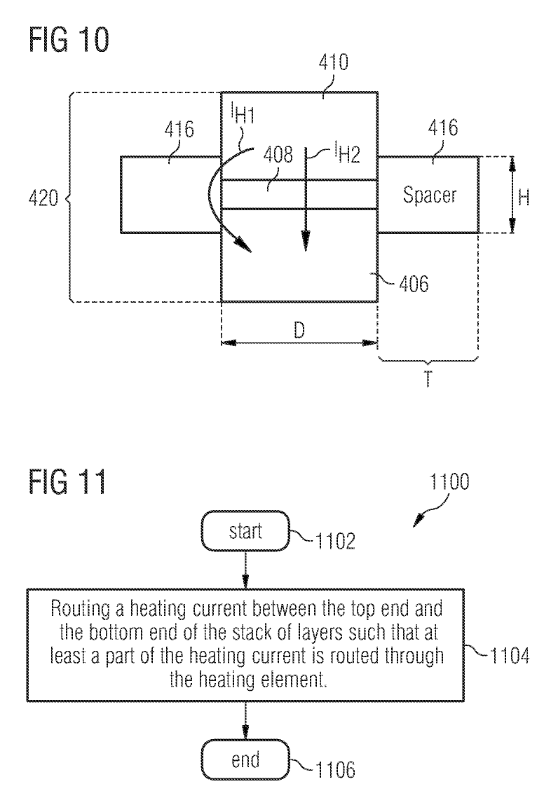

FIG. 9 shows a simulation of the heat power over the temperature within the heating element 416 shown in FIG. 4 thereby assuming that the heating element 416 is germanium, and assuming a voltage of 0.2 V is used to drive the heating current through the heating element 416, and assuming the diameter D of the reference system 406 is 65 nm, and assuming the electric resistance of the barrier layer 408 is 2700 ohm, and assuming the magnetic resistance ratio (MR) of the barrier layer 408 at room temperature is 50%, and assuming that the effective heights H of the heating spacer layer 408 is 5 nm, and its width T of the heating element 416 is 10 nm, as shown in FIG. 10.

The same simulation assumptions have also been made for graph 902 showing a graph of the resistance of the heating element 416 over the temperature. The same conditions are used for obtaining the graphs shown in FIG. 7.

FIG. 11 shows a method 1100 of operating thermal select magneto-resistive memory cell of an integrated circuit according to one embodiment of the present invention. The memory cell includes a stack of layers including a storage memory layer, and a heating element which covers at least a part of the side walls of the stack of layers. At 1102, the method is started. At 1104, a heating current is routed between the top end and the bottom end of the stack of layers such that at least a part of the heating current is routed through the heating element. At 1106, the method is terminated.

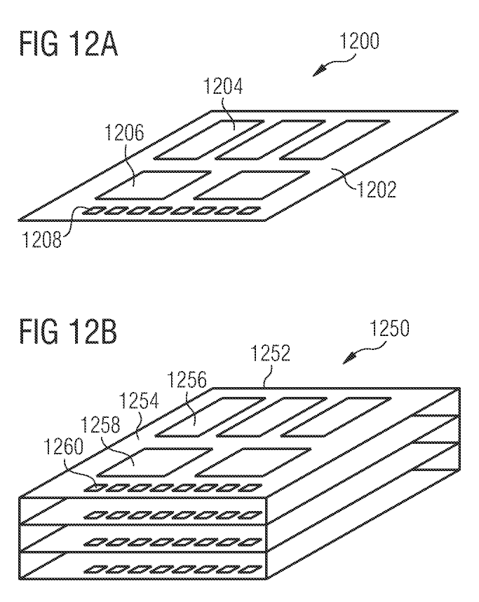

As shown in FIGS. 12A and 12B, in some embodiments, integrated circuits/memory cells such as those described herein may be used in modules. In FIG. 12A, a memory module 1200 is shown, on which one or more integrated circuits/memory cells 1204 are arranged on a substrate 1202. The memory module 1200 may also include one or more electronic devices 1206, which may include memory, processing circuitry, control circuitry, addressing circuitry, bus interconnection circuitry, or other circuitry or electronic devices that may be combined on a module with a memory device, such as the integrated circuit/memory cell 1204. Additionally, the memory module 1200 includes multiple electrical connections 1208, which may be used to connect the memory module 1200 to other electronic components, including other modules.

As shown in FIG. 12B, in some embodiments, these modules may be stackable, to form a stack 1250. For example, a stackable memory module 1252 may contain one or more integrated circuits/memory cells 1256, arranged on a stackable substrate 1254. The stackable memory module 1252 may also include one or more electronic devices 1258, which may include memory, processing circuitry, control circuitry, addressing circuitry, bus interconnection circuitry, or other circuitry or electronic devices that may be combined on a module with a memory device, such as the integrated circuit/memory cell 1256. Electrical connections 1260 are used to connect the stackable memory module 1252 with other modules in the stack 1250, or with other electronic devices. Other modules in the stack 1250 may include additional stackable memory modules, similar to the stackable memory module 1252 described above, or other types of stackable modules, such as stackable processing modules, control modules, communication modules, or other modules containing electronic components.

The present invention further provides a method of manufacturing a thermal select magneto-resistive memory cell including: providing a stack of layers including a storage memory layer; providing a heating element such that the heating element covers at least a part of the sidewalls of the stack of layers, wherein the heating element is provided such that it covers at least a part of the sidewalls of the stack of layers and is electrically coupled to the stack of layers such that a heating current routed between the top end and the bottom end of the stack of layers is at least partly routed through the heating element.

According to one embodiment of the invention, the resistivity changing memory cells are phase changing memory cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory element, a sensing current may routed through the phase changing material (or a sensing voltage may be applied across the phase changing material), thereby sensing the resistivity of the resistivity changing memory element, which represents the memory state of the memory element.

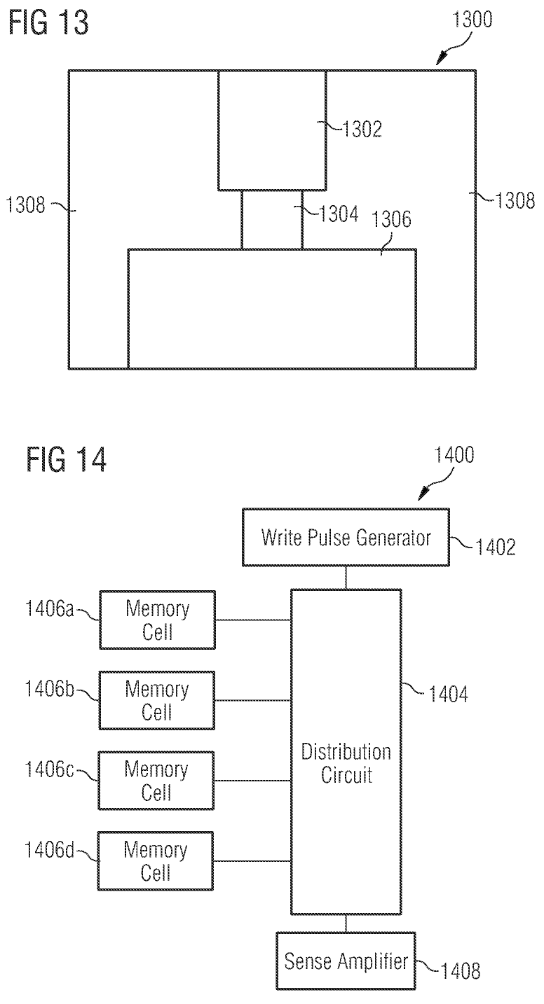

FIG. 13 illustrates a cross-sectional view of an exemplary phase changing memory element 1300 (active-in-via type). The phase changing memory element 1300 includes a first electrode 1302, a phase changing material 1304, a second electrode 1306, and an insulating material 1308. The phase changing material 1304 is laterally enclosed by the insulating material 1308. To use the phase changing memory element, a selection device (not shown), such as a transistor, a diode, or another active device, may be coupled to the first electrode 1302 or to the second electrode 1306 to control the application of a current or a voltage to the phase changing material 1304 via the first electrode 1302 and/or the second electrode 1306. To set the phase changing material 1304 to the crystalline state, a current pulse and/or voltage pulse may be applied to the phase changing material 1304, wherein the pulse parameters are chosen such that the phase changing material 1304 is heated above its crystallization temperature, generally keeping the temperature below the melting temperature of the phase changing material 1304. To set the phase changing material 1304 to the amorphous state, a current pulse and/or voltage pulse may be applied to the phase changing material 1304, wherein the pulse parameters are chosen such that the phase changing material 1304 is briefly heated above its melting temperature, and is quickly cooled.

The phase changing material 1304 may include a variety of materials. According to one embodiment, the phase changing material 1304 may include or consist of a chalcogenide alloy that includes one or more elements from group VI of the periodic table. According to another embodiment, the phase changing material 1304 may include or consist of a chalcogenide compound material, such as GeSbTe, SbTe, GeTe or AgInSbTe. According to a further embodiment, the phase changing material 1304 may include or consist of chalcogen free material, such as GeSb, GaSb, InSb, or GeGaInSb. According to still another embodiment, the phase changing material 1304 may include or consist of any suitable material including one or more of the elements Ge, Sb, Te, Ga, Bi, Pb, Sn, Si, P, O, As, In, Se, and S.

According to one embodiment, at least one of the first electrode 1302 and the second electrode 1306 may include or consist of Ti, V, Cr, Zr, Nb, Mo, Hf, Ta, W, or mixtures or alloys thereof. According to another embodiment, at least one of the first electrode 1302 and the second electrode 1306 may include or consist of Ti, V, Cr, Zr, Nb, Mo, Hf, Ta, W and one or more elements selected from the group consisting of B, C, N, O, Al, Si, P, S, and/or mixtures and alloys thereof. Examples of such materials include TiCN, TIAlN, TiSiN, W—Al₂O₃ and Cr—Al₂O₃.

FIG. 14 illustrates a block diagram of a memory device 1400 including a write pulse generator 1402, a distribution circuit 1404, phase changing memory cells 1406a, 1406b, 1406c, 1406d (for example, phase changing memory cells 1300 as shown in FIG. 13), and a sense amplifier 1408. According to one embodiment, the write pulse generator 1402 generates current pulses or voltage pulses that are supplied to the phase changing memory cells 1406a, 1406b, 1406c, 1406d via the distribution circuit 1404, thereby programming the memory states of the phase changing memory cells 1406a, 1406b, 1406c, 1406d. According to one embodiment, the distribution circuit 1404 includes a plurality of transistors that supply direct current pulses or direct voltage pulses to the phase changing memory cells 1406a, 1406b, 1406c, 1406d or to heaters being disposed adjacent to the phase changing memory cells 1406a, 1406b, 1406c, 1406d.

As already indicated, the phase changing material of the phase changing memory cells 1406a, 1406b, 1406c, 1406d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 1408 is capable of determining the memory state of one of the phase changing memory cells 1406a, 1406b, 1406c, or 1406d in dependence on the resistance of the phase changing material.

To achieve high memory densities, the phase changing memory cells 1406a, 1406b, 1406c, 1406d may be capable of storing multiple bits of data, i.e., the phase changing material may be programmed to more than two resistance values. For example, if a phase changing memory element 1406a, 1406b, 1406c, 1406d is programmed to one of three possible resistance levels, 1.5 bits of data per memory element can be stored. If the phase changing memory element is programmed to one of four possible resistance levels, two bits of data per memory element can be stored, and so on.

The embodiment shown in FIG. 3 may also be applied in a similar manner to other types of resistivity changing memory cells like programmable metallization cells (PMCs), magento-resistive memory cells (e.g., MRAMs), organic memory cells (e.g., ORAMs), or transition metal oxide memory cells (TMOs).

The following description, further exemplary embodiments of the present invention will be explained.

A thermal select process for MRAM (magneto resistive random access memory) cells is based on heating the selected cells to elevated temperatures in order to write information. Usually a resistive barrier (e.g. tunnel barrier) is used to generate the heat for the MTJ heat up. Larger currents and/or large voltages are used which cause reliability issues for very thin barrier materials. As the resistance is usually low to allow the current flow for heating, at a given bias voltage the observed MR is usually relatively low.

According to one embodiment of the present invention, the heating is done in at least one sidewall spacer arranged adjacent to a TJ (tunnel junction) barrier/TJ junction cell. These side wall spacers show a temperature dependent electric conductivity (high resistivity at signal readout at room temperature and low resistivity during writing). The temperature dependent conductivity allows a better magnetic resistance (MR) signal performance at low temperatures during the readout. The side wall spacers may have a very low shunting current that allows almost a full available MR signal from the barrier itself, while for high temperatures during the writing, the side wall spacers can progressively carry more heating current.

As has become apparent, disadvantages of known solutions are reduced MR performance, barrier reliability, high driving voltages, need for thin barriers with low RA product but high MR.

One effect of embodiments of the present invention is that the use of standard barrier materials with a relatively thick barrier and a high MR signal is possible.

One effect of embodiments of the present invention is that almost a full MR can be achieved during signal readout at room temperature.

One effect of embodiments of the present invention is that progressively enhanced heating effects at elevated temperatures can be realized.

One effect of embodiments of the present invention is that low bias voltages can be used.

One effect of embodiments of the present invention is that low electro-stress migration in the barrier can be achieved.

One effect of embodiments of the present invention is that under heating conditions the effective heating power of the parallel and antiparallel resistance state is approaching a symmetric value.

The present invention has been explained mainly using magneto-resistive memory cells as an example. It is to be understood that the present invention may also be applied to arbitrary resistivity changing memory cells, in particular where a heating process is needed.

Within the scope of the present invention “coupled” and “connected” may both mean direct and indirect “coupling” and “connecting”.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising a resistivity changing memory cell,
wherein the memory cell comprises a stack of layers including a storage memory layer,
wherein the memory cell comprises a heating element that covers at least a part of a side wall of the stack of layers and is electrically coupled to the stack of layers such that a heating current routed between a top end and a bottom end of the stack of layers is at least partly routed through the heating element.

2. The integrated circuit according to claim 1, wherein the resistivity changing memory cell is a thermal select magneto-resistive memory cell.

3. The integrated circuit according to claim 2, wherein the heating element covers side walls of a tunneling junction barrier layer.

4. The integrated circuit according to claim 1, wherein an electrical resistance of the heating element decreases when increasing the temperature of the heating element.

5. The integrated circuit according to claim 1, wherein an electrical resistance of the heating element is high at room temperature, and low at temperatures occurring during memory cell writing processes.

6. The integrated circuit according to claim 1, wherein the heating element comprises a semiconducting material.

7. The integrated circuit according to claim 6, wherein the heating element comprises germanium.

8. The integrated circuit according to claim 1, wherein the heating element has a height of about 5 nm to about 10 nm.

9. The integrated circuit according to claim 1, wherein the stack of layers further includes a reference memory layer disposed above or below the storage memory layer.

10. The integrated circuit according to claim 9, wherein the stack of layers further includes a barrier layer disposed between the reference memory layer and the storage memory layer.

11. The integrated circuit according to claim 1, wherein electrical resistances of at least some layers of the stack are chosen such that the majority of a heating current flowing through the memory cell is forced to flow through the heating element.

12. The integrated circuit according to claim 1, wherein the stack of layers comprises a first tunneling junction barrier layer and a second tunneling junction barrier layer disposed above the first tunneling junction barrier layer, wherein a vertical position of a top surface of the second tunneling junction barrier layer is lower than a vertical position of a top end of the heating element, wherein a vertical position of a bottom surface of the first tunneling junction barrier layer is higher than a vertical position of a bottom end of the heating element.

13. The integrated circuit according to claim 1, wherein the heating element comprises a sidewall spacer.

14. A memory cell arrangement comprising a plurality of resistivity changing memory cells,
wherein each memory cell includes a stack of layers,
wherein each stack of layers includes a storage memory layer,
wherein each memory cell comprises a heating element which covers at least a part of a side wall of the stack of layers and is arranged such that a heating current routed between a top end and a bottom end of the stack of layers is split into a first current routed through all layers of the stack of layers, and a second current routed through the heating element.

15. A method of operating a resistivity changing memory cell, wherein the memory cell comprises a stack of layers comprising a storage memory layer, and a heating element which covers at least a part of a side wall of the stack of layers, the method comprising:
routing a heating current between a top end and a bottom end of the stack of layers such that at least a part of the heating current is routed through the heating element.

16. The method according to claim 15, wherein the resistivity changing memory cell comprises a thermal select magneto-resistive memory cell.

17. The method according to claim 16, wherein the heating element covers a side wall of a tunneling junction barrier layer.

18. The method according to claim 15, wherein an electrical resistance of the heating element decreases when a temperature of the heating layer increases.

19. The method according to claim 15, wherein an electrical resistance of the heating element is high at room temperature and low at temperatures occurring during memory cell writing processes.

20. The method according to claim 15, wherein the heating element comprises semiconducting material.

21. The method according to claim 20, wherein the heating element comprises germanium.

22. The method according to claim 15, wherein the heating element has a height of about 5 nm to about 10 nm.

23. The method according to claim 15, wherein electrical resistances of at least some layers of the stack of layers are chosen such that most of a heating current flowing through the memory cell is forced to flow through the heating element.

24. The method according to claim 15, wherein the stack comprises a first tunneling junction barrier layer and a second tunneling junction barrier layer disposed above the first tunneling junction barrier layer, wherein a vertical position of a top surface of the second tunneling junction barrier layer is lower than a vertical position of a top end of the heating element, and wherein a vertical position of a bottom surface of the first tunneling junction barrier layer is higher than a vertical position of a bottom end of the heating element.
